(19) United States
(12) Patent Application Publication
(10) Pub. No.: US 2024/0329177 A1
(43) Pub. Date: Oct. 3, 2024

(54) DEVICE AND METHOD FOR EARLY FAILURE DETECTION OF A MAGNETIC FIELD-SENSITIVE CURRENT SENSOR

(71) Applicant: Sensitec GmbH, Wetzlar (DE)

(72) Inventors: Sven HAUBOLD, Jena (DE); Matthias BRUSIUS, Bad Endbach (DE); Heiko KNOLL, Marburg (DE)

(21) Appl. No.: 18/621,496

(22) Filed: Mar. 29, 2024

(30) Foreign Application Priority Data
Mar. 31, 2023 (DE) 10 2023 108 347.3

(51) Int. Cl. G01R 35/00; G01R 15/20

(52) U.S. Cl. CPC G01R 35/00; G01R 15/207

(57) ABSTRACT

A device for detecting an error-free operation with a magnetic-field-monitored busbar or conductor loop for current measurement based on a magnetic-field-sensitive sensor element. The busbar or conductor loop is formed in a measurement plane of the current sensor and can be sensed at least in a measurement region by the current sensor based on a magnetic-field-sensitive effect. The test conductor loop is arranged in spatial proximity to the conductor loop sensed by the current sensor, the test conductor loop being arranged in a plane which is parallel to the measurement plane of the sensed conductor loop and is adapted to a main current path predetermined by the conductor loop such that a modulated test current introduced into the test conductor loop can be sensed in a magnetic-field-sensitive manner in the measuring region of the current sensor together with a current in the main current path.

### PRIORITY CLAIM

The present application claims priority to German Patent Application No. 10 2023 108 347.3, filed on Mar. 31, 2023, which said application is incorporated by reference in its entirety herein.

### FIELD OF THE INVENTION

The invention is directed to a device and a method for detecting an error-free operation of a current sensor based on a magnetic-field-sensitive sensing element which is preferably formed as a gradient sensor, comprising a busbar or conductor loop formed in a measurement plane of the current sensor, particularly for early detection of failure phenomena of current sensors in safety-related fields, preferably in power electronics of electric drives, for example, in automobiles with electric drive.

### BACKGROUND OF THE INVENTION

Various methods for checking or detecting faulty measurement of magnetic-field-sensitive current sensors are known from the prior art but either work redundantly with a plurality of current sensors or require a currentless main current path or at least a currentless conductor loop to be sensed for a plausibility test phase. Other measuring systems based on the use of auxiliary windings on ferromagnetic cores are very bulky, sluggish and usually require that the main current conductor is mechanically guided through the ferromagnetic core, which is not without an effect on the main current. In simple shunt measuring systems, galvanic isolation is lacking and additional energy losses occur at the shunt.

In DE 10 2012 215 946 A1, for example, the current to be measured is fed across a shunt resistor and the occurring voltage drop is measured. By means of a second resistor connected in parallel, an additional defined current flow is generated which can be used for the differential current test. Additional losses, e.g., in the form of heat, are incurred through the use of shunt resistors, which can be quite problematic at correspondingly high currents. Due to the absence of galvanic isolation, the measuring system must be designed for any voltages and currents which might possibly occur.

A current sensor for measuring the magnetic fields caused by the current-carrying conductors is known, for example, from US 2012/0319473 A1. The conductor through which current flows is surrounded by a core material on which, in addition to the actual current measuring coil, additional windings are mounted for inductively impressing a test current. Accordingly, the current sensor itself is not easily isolatable. In addition, the test magnetic field generated in the test windings must be high enough that the differential current can also be reliably detected; that is, the current measurement is designed only for very high currents and is very insensitive so that the impressed test current must also be sufficiently high in order to be reliably detected.

Further, a method is known from WO 2006/042839 A1 for measuring an external magnetic field with a magnetoresistive sensor, a generator module for generating an additional field in the region containing the magnetoresistive sensor and with a control unit which, in a first step, controls the generator module to apply an additional magnetic field pulse with a first value of a first polarity and strength which saturates the magnetoresistive sensor and which, in a second step, applies a second value of the additional magnetic field which does not saturate the sensor in order then to determine the value of the external magnetic field to be measured by measuring the resistance with the magnetoresistive sensor. The first step is preferably carried out in situ before each measurement of the external magnetic field in order to systematically and accurately correct any drift in the sensor sensitivity.

Further, EP 1 327 891 B1 describes a magnetic field sensor and an ammeter. Structures are formed on a substrate as diagonal or perpendicular walls relative to a main substrate plane which are preferably formed as channels or ridges for generating variously oriented magnetic-field-sensitive layers at different angles. A magnetic field sensor outfitted in this manner is then used in a current sensor such that the magnetic effect of the current flow in a conductor at the location of the magnetic field sensor is utilized for determining the current strength.

### SUMMARY OF THE INVENTION

It is the object of the invention to find a novel possibility for detecting an error-free operation of current sensors with magnetic-field-sensitive sensing by which the main current path which is measured in a magnetic-field-sensitive manner in a busbar or conductor loop to be sensed can be checked regularly or spontaneously with no interruption of current flow (in situ) without influencing, falsifying or even temporarily interrupting the measured current flow in the busbar or conductor loop to be sensed. Further, a method is to be provided for checking the error-free operation of current sensors with magnetic sensing which permits a timely detection of failure phenomena.

In a device for detecting a faulty operation of a current sensor based on a magnetic-field-sensitive sensor element which is preferably formed as gradient sensor, comprising a sensed busbar or conductor loop which is formed in a measurement plane of the current sensor and which can be sensed by the current sensor at least in a measuring region, the above-stated object is met according to the invention in that a test conductor loop is arranged in spatial proximity to the busbar or conductor loop to be sensed by the current sensor, wherein the test conductor loop is arranged in a plane which is parallel to the measurement plane of the sensed busbar or conductor loop and is adapted to a main current path predetermined by the busbar or conductor loop such that a modulated test current introduced into the test conductor loop can be sensed in a magnetic-field-sensitive manner in the measuring region of the current sensor together with a current in the main current path.

In the context of the invention, by “magnetic-field-sensitive current measurement” or “magnetic-field-sensitive current sensor” is meant a current measurement which is based on a change in the electrical resistance of a material accompanying change in an external magnetic field. This includes, in particular, the anisotropic magnetoresistance effect (AMR effect), giant magnetoresistance effect (GMR effect), the colossal magnetoresistance effect (CMR effect), the tunnel magnetoresistance effect (TMS effect) and the planar Hall effect.

The test conductor loop is advantageously connected to a test current generator for generating a modulated or pulsed test current. The test conductor loop and the test current generator are preferably completely galvanically isolated from the conductor loop or busbar of the main current path.

The test conductor loop is advisably formed under the current sensor as a test conductor path parallel to the predetermined main current path of the conductor loop/busbar.

The test conductor loop is preferably integrated by multilayer thin-film technology on a sensor printed circuit board of the current sensor as test conductor layer(s) of the conductor loop parallel to the predetermined measurement plane with test conductor paths parallel to the predetermined main current path of the conductor loop. However, it can also advantageously be implemented as conductive frame parallel to the predetermined main current path in one or more layers on a chip of the magnetic-field-sensitive sensor element of the current sensor.

In a preferred construction, the test conductor loop is formed as a kind of helical shape with a plurality of parallel conductor path portions with respect to the predetermined main current path of the busbar/conductor loop sensed by the current sensor. In so doing, it can also be applied as double helix in different layers of a carrier printed circuit board of the current sensor.

The test current generator is advantageously a pulse generator for generating defined current pulses. In this regard, it is preferable that the test current generator has at least one switching transistor for generating pulses, a pulse length limiter and a current limiter. Further, the test current generator can have a series capacitor as pulse length limiter and a fixed resistor as current limiter.

In a particularly preferable manner, the switching transistor is formed by at least one element from the group comprising unipolar transistors, bipolar transistors, thyristors or an optoelectronic switching element. The test current generator advantageously comprises a pulse generator for generating individual pulses comprising rectangular pulse, sawtooth pulse or sine pulse or pulse sequences therefrom as recurrence of identical or different pulse shapes. Further, the test current generator can also be configured so as to generate a freely defined pulse sequence which can be learned for evaluation preferably with pattern recognition algorithms.

The device according to the invention is directed to current sensors based on a magnetic-field-sensitive effect preferably formed as gradient sensor, but can be applied in a generalized manner for any magnetic sensors, since the type of magnetic-field-sensitive sensor element used is not relevant to the functionality of the invention. That is, the test principle of the invention can be realized using AMR sensors, CMR sensors, EMR sensors, GMR sensors, TMR sensors (collectively: xMR current sensors) as well as for sensors based on the Hall effect.

The above-stated object is further met by a method for detecting a faulty operation of a current sensor based on a magnetic-field-sensitive effect at a conductor loop or busbar sensed for current measurement, comprising the following steps:
A. providing an additional sensable test conductor loop arranged adjacent to the busbar or conductor loop sensed in a magnetic-field-sensitive manner by the current sensor for applying a modulated test current,
B. detecting first measurement values by means of the current sensor for successive current measurement and current monitoring in a predetermined measuring region of the sensed busbar or conductor loop,
C. generating a modulated test current by means of the test current generator,
D. introducing the modulated test current into the test conductor loop in a temporally limited manner,
E. detecting second measurement values through current measurement by means of the current sensor with overlaying of magnetic fields of the test current in the test conductor loop and of the current in the busbar or conductor loop which is sensed in a magnetic-field-sensitive manner by the current sensor,
F. determining a differential current from the first measurement value and second measurement value and evaluating the differential current for detecting deviations of the differential current from the waveform of the introduced test current.

The test current of the method is preferably provided as individual pulse. However, it can also be provided as a defined pulse sequence.

In this regard, it is advantageous that the test current is provided as a rectangular pulse, sawtooth pulse or sine pulse or in the pulse sequence therefrom as recurrence of identical or different pulses. However, it can also be generated as freely defined pulse sequence and possibly learned for evaluation with pattern recognition algorithms.

The basic concept of the invention is based on the idea that by means of a conductor structure which is additionally introduced under a conventional xMR current sensor and which, as planar formed conductor loop, is acted upon temporarily by a test current generator with a modulated test current, e.g., individual pulse or defined pulse sequence, a defined and temporally limited magnetic field is superposed on the xMR current sensor as additional offset to the magnetic field caused by the current to be measured in the main current path of the busbar and can be detected as magnetic field modulation in that the offset portion is isolated from at least two consecutively recorded current measurement values with and without application of test current and is compared with the test current profile emitted by the test current generator.

The fields of use of the test method according to the invention for xMR current sensors are unlimited and can extend from control electronics of vehicle drives to power electronics in aircraft, ships and spaceflight and monitoring of fast chargers or frequency inverters. By means of this method, demanding safety requirements from simple BIST (built-in self-test) to complex test flows during active device operation can be met quickly and precisely and are accordingly potentially suitable for all fields of use for ensuring functional safety (e.g., SIL level and ASIL level, failure safety, personal protection, and so on).

By means of the device according to the invention and the method upon which it is based, it is possible to check the error-free operation of current sensors with magnetic sensing without the measured current flow in the conductor loop to be sensed being influenced or falsified or requiring an interruption in testing in order for failure phenomena of the magnetic-field-sensitive current sensor to be detected in a timely manner.

### BRIEF DESCRIPTION OF THE DRAWINGS

The invention will be described in more detail in the following by means of embodiment examples referring to drawings. The drawings show:

FIG. 1 a current sensor for detecting a faulty operation which is provided with an additional test conductor loop according to the invention, which current sensor is arranged over the test conductor loop on a carrier printed circuit board above a busbar or conductor loop of a main current path, which busbar or conductor loop is to be sensed;

FIG. 1A a current sensor which is mounted according to FIG. 1 on a carrier printed circuit board with test conductor loop in which the carrier printed circuit board has, on a surface remote of the current sensor, the sensed conductor loop of the main current path opposite the test conductor loop and current sensor;

FIG. 2 three exemplary embodiment forms of the test conductor loop according to the invention with adapted test conductor geometry depending on the required magnetic field suited to the sensitivity of the current sensor and to the geometry and magnitude of the magnetic field typically generated by the main current path;

FIG. 3 an advantageous configuration of a test current generator for generating a modulated test current for temporarily acting upon the test conductor loop with a test pulse generated by means of switching transistors and pulse current limiting and pulse length limiting;

FIG. 3A a further advantageous construction of a test current generator for generating a modulated test current with an n-channel MOSFET as preferred switching transistor for pulse generation;

FIG. 3B a further exemplary construction of a test current generator for generating a pulsed test current with monostable multivibrator with NAND gates for pulse current limiting and pulse length limiting;

FIG. 3C a further advisable construction of a test current generator for generating a pulsed test current with a monostable multivibrator by means of timers for pulse current limiting and pulse length limiting IC;

FIG. 3D a further advantageous construction of a test current generator for generating a modulated test current with an n-channel MOSFET controlled by microcontroller for simultaneous pulse length limiting;

FIG. 4 a preferred construction of the current sensor according to the invention with a circuit for failure monitoring utilizing components of typical sensor circuitry;

FIG. 5 a flowchart for the method according to the invention for detecting the faulty operation of a current sensor without influencing the main current path to be sensed;

FIG. 6 an exemplary recorded current profile with possible evaluation modes of the test pulse monitoring with different main current behavior;

FIG. 7 a preferred sensor circuit of a current sensor monitored according to the invention utilizing programmable hardware with IP core for implementing the method according to the invention.

### DETAILED DESCRIPTION

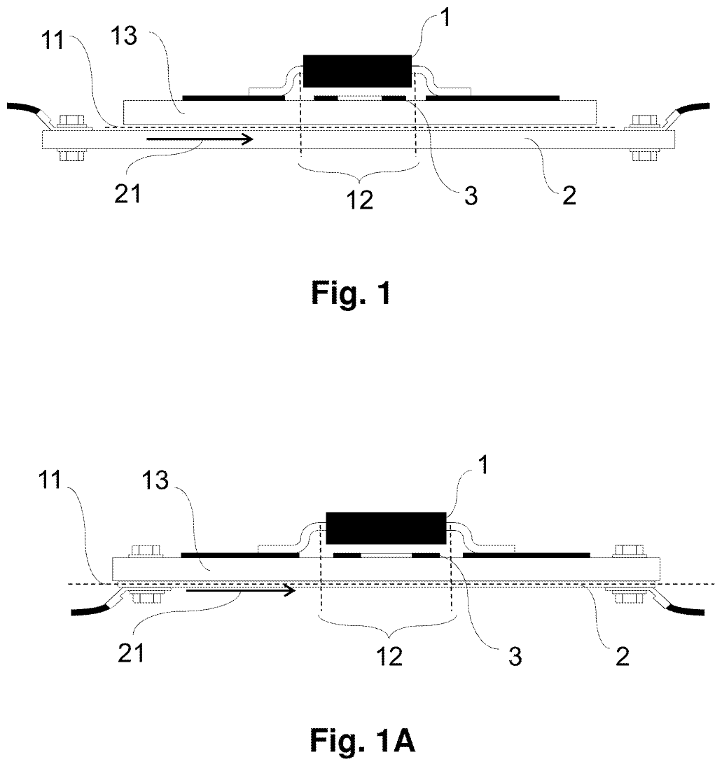

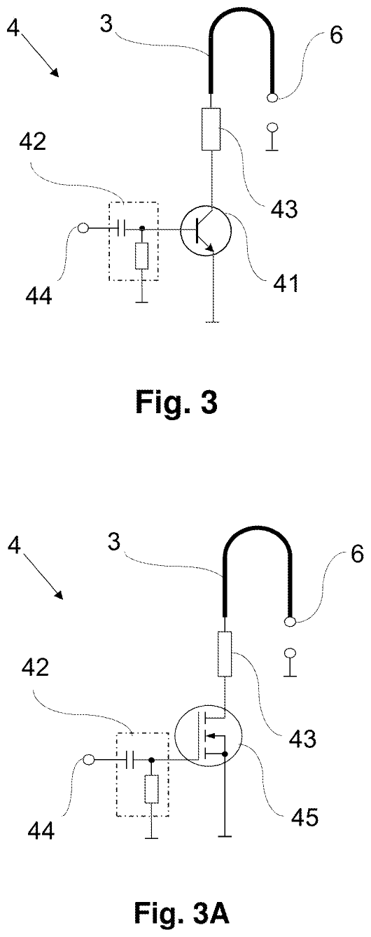

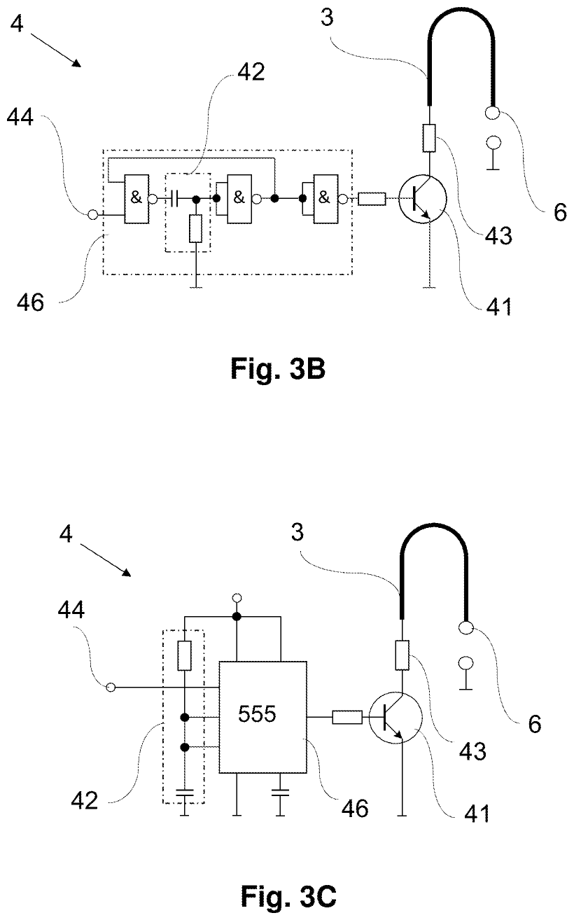

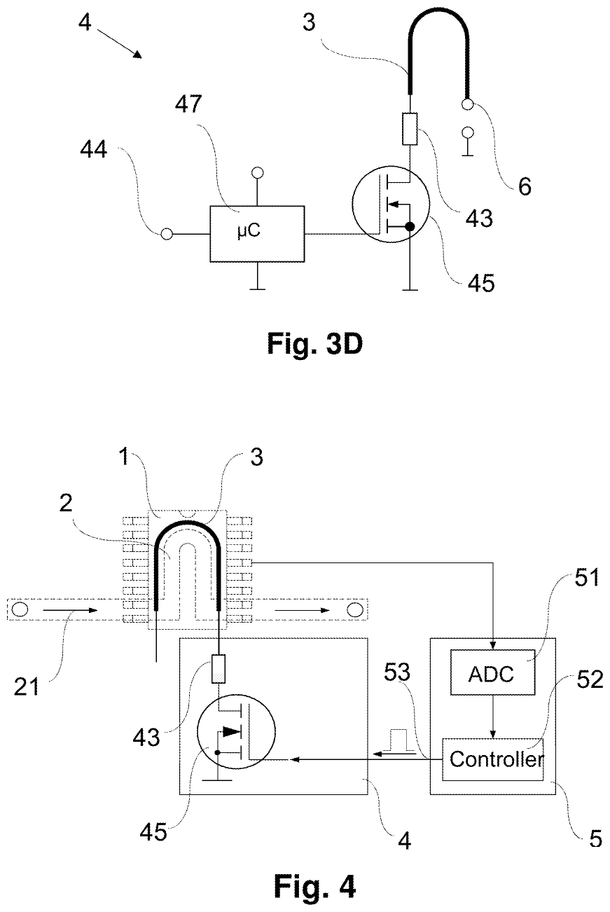

In a basic variant, the device for detecting a faulty operation of a current sensor 1 based on a magnetic-field-sensitive sensor which is preferably formed as a gradient sensor according to FIG. 1 comprises the current sensor 1, a sensed main current path in the form of a busbar or conductor loop 2 (hereinafter conductor loop 2 for the sake of brevity), a test conductor loop 3 and a test current generator 4 (shown only in FIGS. 3, 4 and 7) which supplies the test conductor loop 3 with a modulated test current temporarily, i.e., limited to a brief period of time.

In the following embodiment examples, an xMR current sensor 1 is designated for current measurements as an abbreviation for all magnetic-field-sensitive current sensors 1, e.g., based on the AMR effect, GMR effect, CMR effect, TMS effect as well as for sensors utilizing the planar Hall effect. Accordingly, any of the above-mentioned sensors can be selected.

According to FIG. 1, a selected xMR current sensor 1, preferably an AMR sensor, is mounted on a simple carrier printed circuit board 13 which is commonly also utilized for the circuitry of the current sensor 1 fabricated as an integrated circuit (IC). Depending on the anticipated current flow and/or the required galvanic isolation, this construction can either be placed over a solid conductor loop 2 to be sensed (U-shape or Ω-shape is preferred in gradient sensors) or the main current path 21 can likewise be applied as traces to the surface of the carrier printed circuit board 13 opposite the current sensor 1 (FIG. 1A) or incorporated in an inner layer of the carrier printed circuit board 13 (not shown), a galvanic isolation being provided at the same time by means of the carrier material. There is a gap between the carrier printed circuit board 13 and the current sensor 1 (when soldered to the carrier printed circuit board 13) which can be utilized for mounting the test conductor loop 3 on the carrier printed circuit board 13. The test conductor loop 3 has preferably been applied as test conductor layer 31 using thin-film technology and subsequently etched in suitable test conductor paths 32.

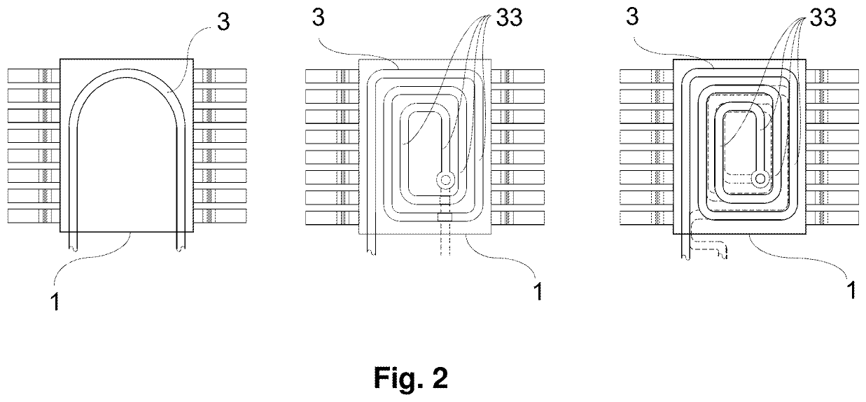

The shape and orientation of the test conductor loop 3 or its test conductor path(s) 32 are governed by the shape of the main current path 21 of the conductor loop 2 to be sensed. In this regard, as many partial areas of the planar test conductor loop 3 as possible are to be oriented parallel to the course of the conductor loop 2 as is shown in FIG. 2 in the form of the parallel test conductor path portions 33. In principle—although the main current path 21 is not positioned directly opposite the carrier printed circuit board 13—the position of the carrier printed circuit board 13 defines a measurement plane 11 of the current sensor 1 to which the planes and the conductor loop 2 to be sensed as well as the test conductor loop 3 are oriented in parallel. At the same time, the measuring region 12 of the current sensor 1 in which the conductor loop 2 and test conductor loop 3 are positioned more or less one above the other is determined by the lateral spatial extent of the current sensor 1 (set up as IC module). The test conductor loop 3 is preferably closer to the current sensor 1 in order to obtain a sufficient magnetic field for superposition with the field of the main current path 21 at lower test currents.

Selected examples for the configuration of the test conductor loop 3 which are well suited to the U-shape (shown only in dashes in FIG. 4) of the conductor loop 2 to be sensed and to the AMR sensor type are shown in three subdiagrams in FIG. 2. The most important feature common to all three shapes is the test conductor path portions 33 which are oriented parallel to the conductor loop 2 and which ensure a sufficiently uniform superposition distance of the magnetic fields of the two currents (test conductor current and current in the main current path 21) within the measuring region 12 of the current sensor 1. For the test method, the narrow test conductor loop 3, whose geometry may be carried out differently depending on the necessary sensitivity of the xMR current sensor 1, is mounted directly under the current sensor 1 on the carrier printed circuit board 13. In most cases in which high currents of power electronics are to be measured, it is sufficient, as shown in the first subdiagram in FIG. 2, to form the test conductor loop 3 with only one conductor path 31 which is adapted to the conductor loop 2 formed in U-shaped or Ω-shaped manner in the main current path 21 and is ideally duplicated directly parallel to the latter. However, the portion of the magnetic field strength generated by the test conductor loop 3 must always be higher than the magnetic field strength generated by the main current path 21 by an additional amount in order to measure the additional test current as sufficiently distinct offset to the magnetic field generated by the conductor loop 2 and to reliably isolate it from the measurement value of the main current path 21.

The lower the sensitivity of the current sensor 1 or the weaker the effect of the magnetic field of the conductor loop 2 to be sensed on the current sensor 1, the greater the quantity of narrow test conductor paths 32 that must be selected which are oriented parallel to the conductor loop 2 of the main current path 21. The variant of the test conductor loop 3 shown in the second subdiagram in FIG. 2 takes the above-mentioned situation into account in that a helical shape, shown schematically, is selected for the test conductor path 32 with a plurality of parallel test conductor path portions 33 oriented parallel to the conductor loop 2 (only visible in FIG. 4) so that the occurring magnetic fields of the individual test conductor path portions 33 add up.

In the third subdiagram of FIG. 2, the quantity of test conductor path portions 33 is increased even more by mounting a double-helix shape running in the same direction in a plurality of layers of the carrier printed circuit board 13. Accordingly, the cumulative test conductor magnetic field from all of the magnetic field portions of the individual test conductor path portions 32 is even appreciably greater.

The planar arrangement of the test conductor loop 3 is not limited to a conductor structure on the carrier printed circuit board 13 outside of the xMR current sensor 1 but rather can also be integrated directly in the xMR current sensor 1, technical and design possibilities permitting. In every case, the test conductor loop 3 must be shaped in such a way and located (in position and orientation) in such a way that it provides a required test pulse current with sufficiently high field strength parallel to the main current path 21 for the xMR current sensor 1. The layer thickness and the conductor path width of the test conductor loop 3 can be virtually freely selected and predetermined in a mathematically defined manner within manufacturing capabilities. The occurring magnetic field must have a sufficiently great distance from the known measurement tolerance of the xMR current sensor 1. The current strength or step height of the test pulses must be dimensioned in such a way that the xMR current sensor 1 is not driven into saturation with the maximum expected main current to be measured. The test current should be selected as low as possible from an energy perspective.

FIG. 3 shows an exemplary construction for a possible basic principle of the test current generator 4 of the device according to the invention. In the area of the test conductor loop 3, shown exclusively, the current sensor 1 and the conductor loop 2 which would be situated above or below the drawing plane are omitted in FIG. 3 for the sake of clarity. The test current generator 4 in this example is formed as a pulse generator 41 by means of a switching transistor which emits an approximately rectangular pulse. This can be carried out by means of a unipolar transistor, bipolar transistor (NPN/PNP), thyristor or optoelectronic switching elements or, ideally, by means of a MOSFET. The actual test pulse length is defined by a pulse length limiter 42 in the form of a series capacitor and by a current limiter 43 in the form of a fixed resistor but can also be limited by means of other electronic circuit solutions or defined by control logic as will be specified in the following referring to FIGS. 3B-3C. Accordingly, even during a malfunction, no continuous current can form in the test conductor loop 3 at the input 44 of the test current generator 4. In this way, the pulse length limiter 42 and the current limiter 43 protect against a possible overloading of the switching transistor. When the switching transistor as pulse generator 41 is correspondingly controlled at the input 44 of the test current generator 4 and fed by a main current supply 6, the test current generator 4 preferably emits a rectangular pulse in the test conductor loop 3.

The maximum test current flow is adjusted by means of a defined current limiter 43, for example, by means of a fixed resistor (as is shown in FIGS. 3, 4 and 7). A pulsed operation via a switchable constant current source instead of the pulse generator 41 is also possible. The test current generator 4 can preferably have its own current supply 6 (galvanic isolation) which does not depend on the measuring system (current sensor 1 at main current path 21) but can also be coupled with the main current path 21 if the latter is connected directly to the current supply 6, for example. However, this has the drawback that the galvanic isolation is canceled. The advantage of an independent current supply 6 consists in that the test pulse currents can be generated at any desired point in time independently from the effective current flow of the actual main current path 21.

In a construction of the test current generator 4 according to FIG. 3A, the test pulse generator 41 is ideally formed by a MOSFET in order to keep power losses as low as possible and so as not to bring about additional losses in the test conductor loop 3. In order to limit the duration of the flowing test pulse current so as to prevent possible continuous test currents in case of defect, a time-limiting element is integrated in addition. In FIG. 3, this pulse length limiter 42 is realized by means of a simple RC circuit which only passes a short pulse for controlling the MOSFET 45. The test current generator 4 must generally be capable of delivering a defined current pulse having a determined level which is defined by the sensitivity of the xMR current sensor 1 and brings about sufficiently high current spiking in the current sensor 1 and having a defined duration which is determined by the minimum reaction time of the xMR current sensor 14 for current measurement. The maximum possible flowing test pulse current is limited by a fixed current limiting, for example, by means of a fixed resistor as current limiter 43. The circuit principle is very simple. First, the actual current flowing through the conductor loop 2 to be sensed with the xMR current sensor 1 is detected as current measurement value. Next, the test current generator 4 is triggered. If a positive switching signal is applied to the triggering input 44 of the test current generator 4, a current starts to flow through the capacitor of the pulse length limiter 42, which current is limited by the associated resistor of the RC circuit so that the capacitor cannot be charged too quickly. As a result of the impedance of the capacitor, the MOSFET 45 is initially turned on and a current flow determined by the current limiter 43 results via the test conductor loop 3. Only then can the current measurement take place with the additional test current offset by means of the xMR current sensor 1. When the charging of the capacitor of the pulse length limiter 42 reaches the shut off threshold of the MOSFET 45, the MOSFET 45 blocks the test current via the control loop 3 again. When the input 441 of the test current generator 4 is set at 0 V again, the capacitor of the pulse length limiter 42 is automatically discharged again and the test current generator 4 is available again for a new test current pulse. The length of the test pulse is determined by the capacitance of the capacitor, the nominal value of the resistor and the switching thresholds of the MOSFET 45.

FIG. 3B and FIG. 3C show further possible variants of the pulse generator 41 for realizing the test current generator 4. These variants operate on the monostable multivibrator principle.

As is shown in FIG. 3B, the control of the monostable multivibrator can be carried out by means of standard logic NAND gates and an RC element. This circuit has the advantage over FIG. 3A that the RC charging/discharging circuit is decoupled from input 44 as well as from the switching transistor of the pulse generator 41 and accordingly enables a more constant time limiting.

In FIG. 3C, the further circuit variant with a typical timer IC 46 (e.g., NE555, CA555, TLC555, and so on) is constructed as time-limiting element. In this example, a bipolar NPN transistor is used as pulse generator 41, but this may also be constructed as a MOSFET 45.

FIG. 3D shows an exemplary variant for the test current generator 4 with a microcontroller 47. The time limiting in this case is controlled digitally in the program code of the microcontroller 47 and no external resistors or capacitors for timing are needed. Accordingly, determined parasitic influences, e.g., temperature, which act on the passive components (RC circuits) of the previous examples can be eliminated and a synchronization with the test measurements for detecting the test pulses can be facilitated.

Through the use of monostable multivibrators which was described above, no continuous current which would falsify the test results and the current measurement of the main current path 21 can arise in the test pulse loop 3 even in case of a malfunction at the control signal of the test current generator 4. Additionally, the current limiter 43 and the pulse generator 41 in the form of a simple switching element are protected against a possible overload through continuous current in case of a defect. Defects occurring in this circuit area can likewise be reliably detected by the test method according to the invention. For example, if the differential current value I_{D} does not change after the test current pulse is triggered and the current measurement from the main current path 21 lies within an expected value window, it can be concluded that there is a defect in the pulse generator 41.

For a BIST functionality (built-in self-test), this test can also be carried out, for example, in a currentless main current path 21, i.e., for example, the functionality of the test current generator 4 itself can be tested initially after the device to be monitored is switched on before the actual main current path 21 is activated. The test current generator 4 can have its own current supply 6 (e.g., for a galvanic isolation) which is independent from the measuring system (current sensor 1) but can also be coupled with the control loop 2 when the latter is connected, for example, directly to a main current supply. However, this has the disadvantage that the galvanic isolation is canceled. The advantage of an independent current supply consists in that the test pulse currents can be generated at any desired point in time independently from the effective state and current flow of the actual main current path 21. If a simple energy storage (e.g., capacitor which is cyclically charged) is used for the current supply 6 of the test pulse generator 4, a simple existing GPIO pin 53 of an integrated circuit 52 or other existing current supply (e.g., also energy gained from the control loop 2 by energy harvesting) can also be used.

In case of a fast reaction time of the xMR current sensors 1 to changes in current, the pulse current duration can be selected to be very short (e.g., less than 50 μs in AMR current sensors). Accordingly, energy considerations are also taken into account, and very short reaction times can also be achieved in case of defects, which is very important, for example, in safety-related systems. Defects occurring in the sensor circuitry 5 can be reliably detected by the test method. The provided test current can be generated in various ways. It must be capable of delivering a defined current pulse at a determined level and determined time, e.g., 80 to 200 mA, preferably 100 mA, in a typical AMR current sensor for at least 50 μs.

A typical overall construction of the device for detecting a faulty operation of a current sensor 1 is shown in FIG. 4. The test method can easily be integrated in existing current measuring systems without requiring additional lines or modifications to the existing system layout. This is possible because the evaluating electronics (analog-to-digital converter [ADC] 51 and microprocessor/microcontroller 52 in FIG. 4) which are already present for normal current measurement are used in conjunction for measuring the generated test current offset. Accordingly, no additional hardware is required apart from the test current generator 4. Merely a simple switchable output pin 53 (e.g., GPIO [general-purpose input/output pin]) is needed for defined control of the pulse generator 41. The test pulse length need merely be adapted to the required maximum pulse duration based on the maximum reaction time of the xMR current sensor 1 and to the sensing speed (sample rate). Longer times are limited through the use of a pulse-limiting component (e.g., capacitor of the pulse length limiter 43) or time-determining components (e.g., monostable multivibrators, timer ICs or microcontrollers). The test current generator 4 is only shown schematically in FIG. 4 but corresponds at least to the variants of the test current generator 4 disclosed in FIG. 3 and FIGS. 3A-3D.

Further, it is possible that the test current generator 4 automatically generates periodic test current pulses (e.g., with the aid of an astable multivibrator 46) and signalizes the respective active phase via a signal to the evaluating electronics. Accordingly, the evaluating electronics can distinguish between an active state and inactive state of the test current generator and can assign the measured current value with or without additional test pulse current offset. Building on this testing principle, the test current generator and, therefore, the testing principle can also synchronize directly with the switching frequency of inverters to be monitored so that the measurements can always take place within the active or inactive switching cycles of the inverter. Because of the short conversion times of the xMR current sensor 1, it is also easily possible to take a plurality of consecutive measurements of the differential current value I_{D}.

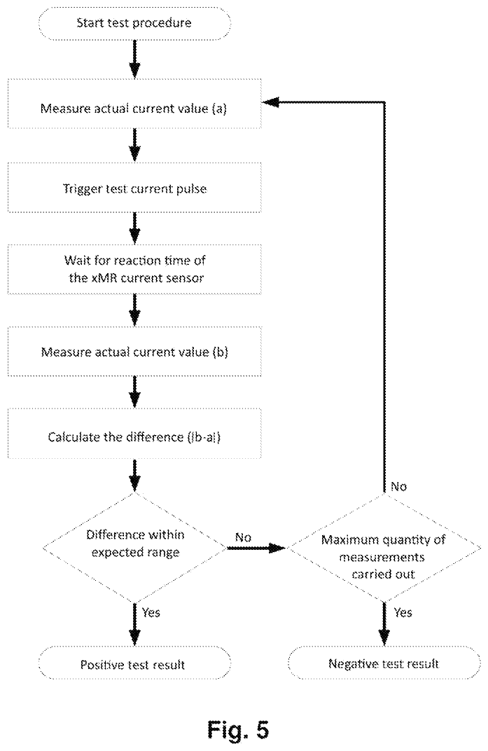

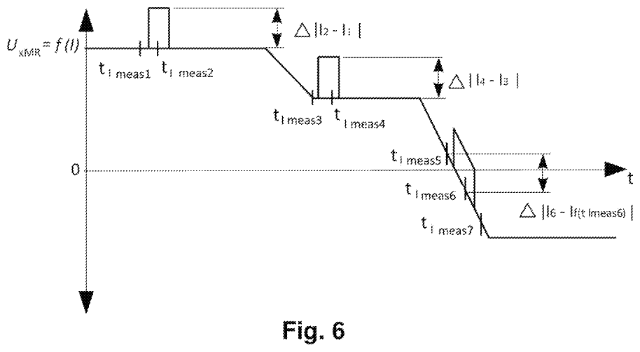

The method according to the invention for detecting a faulty operation of a current sensor 1 is shown in FIG. 5. The plausibility measurement principle contained therein is based on a simple cyclical differential current measurement. In FIG. 5, the method is shown as a flowchart by which the test principle according to the invention can be implemented. First, the current actually flowing on the main current path 21 is determined by means of the xMR current sensor 1 and a downstream analog-to-digital converter ADC 51. The triggering of a test current generator 4 is then carried out, as a result of which a test pulse or a short pulse sequence is fed to the test conductor loop 3 and, after a short wait, a new measurement of the actual current value, which is now composed of the sum of the current value of the main current path 21 and the additionally applied test current (to be exact: the sum of the magnetic fields proportional to the current), is carried out. The waiting period is necessary so that the modulated test current and, therefore, the magnetic field can appear to the full extent and the reaction time of the xMR current sensor 1 is achieved for the correct current measurement value. At this point, the resulting measurement current value of the xMR current sensor 1 arises from the current flow of the main current path 21 and of the additional defined test current which is limited by a resistor of the current limiter 43. The differential current amount I_{D} is now determined from the measurement values which are very close in time before and during the actively flowing test current. An additional measurement safety can be achieved by means of a subsequent third measurement which is again carried out without active test pulse current (see also FIG. 6).

In order that any sudden changes in current on the main current path 21 between the differential current measurements I_{D} are not detected as pseudo-errors, the test method can be applied sequentially multiple times until a maximum allowable iteration number predetermined for the application is reached. The calculation of the current differential amounts I_{D} from the two current measurement values, without test current and with test current, gives the measured test current value. This value must lie within an expected tolerance range. If the determined test current lies outside of this tolerance range and the maximum iteration number predetermined for the application is still not reached, a new differential current measurement is taken, first without test current and then again with test current. If the maximum iteration number predetermined for the application is reached, the xMR current sensor or the current sensor circuitry is defective and the necessary safety measures can be undertaken. If the determined differential current value I_{D} lies within the tolerance range and the maximum iteration number is not yet reached, the test results are successful and plausible.

FIG. 6 shows the procedure schematically in a graph. First, a normal differential current measurement is shown with two measurement points, one before the triggering of the test current generator 4 with measurement value t_{I meas1} and one after the triggering of the test current generator 4 with measurement value t_{I meas2}. The resulting offset Δ|I₂−I₁| of the test pulse current on the main current during the current measurement is shown schematically at time t_{I meas2}. A further validation of the plausibility of the measurement values, e.g., when the main current value changes during the current measurement, can be carried out by means of a new current measurement after the conclusion of the test pulse and subsequent linearization of all three current measurement values for determining the actual current offset value through the test pulse current. To this end, the linearly approximated function equation for the change in current of the main current path is first calculated at this point from the current measurements t_{I meas3} before the triggering of the test current pulse generator 41 and after the termination of the test current pulse (EQ. 1).

In this way, the current value of the main current path 21 which is necessary for the amount of the current difference relative to the test pulse current for the test method according to the invention can be determined in an approximated or linearized manner at point t_{I meas4}

$$I ( t ) = \frac{{I}_{meas 7} - {I}_{meas 5}}{{t}_{Imeas 7} - {t}_{Imeas 5}} \cdot ( {t}_{Imeas 6} - {t}_{Imeas 5} ) + {I}_{meas 5} \qquad ( EQ . 1 )$$

The differential current amount I_{D} can then be calculated by equation 2 at point t_{I meas6} which lies in the middle between the time points of current measurements t_{I meas5} and t_{I meas7} to simplify the calculation.

$$Δ {I}_{tImeas 6} = {I}_{meas 6} - \frac{{I}_{meas 7} - {I}_{meas 5}}{{t}_{Imeas 7} - {t}_{Imeas 5}} \cdot ( \frac{{t}_{Imeas 7} - {t}_{Imeas 5}}{2} ) + {I}_{meas 5} \qquad ( EQ . 2 )$$

If the differential current amount I_{D} lies outside of a determined value range (window), there is a problem with the xMR current sensor 1 or with the test current generator 4 and suitable safety measures can be introduced.

The test method can be implemented with a power supply 6 of the test current generator 4 separate from the main current path 21 also with negative currents on the main current path 21, e.g., during recuperation phases (energy recovery). Accordingly, the test method is completely independent from the main current flow direction, since only the differential amounts of the measured currents at the respective measuring time points (according to FIG. 5) are detected. The test method according to the invention can be applied with DC as well as with AC or pulsed main currents.

Such test methods during operation are an essential component of the necessary safety requirements precisely in the industrial manufacturing process or in the automotive field. The great advantage of this invention consists in the possibility of applying this test method at any time during operation (in situ) and accordingly ensuring timely detection of malfunction.

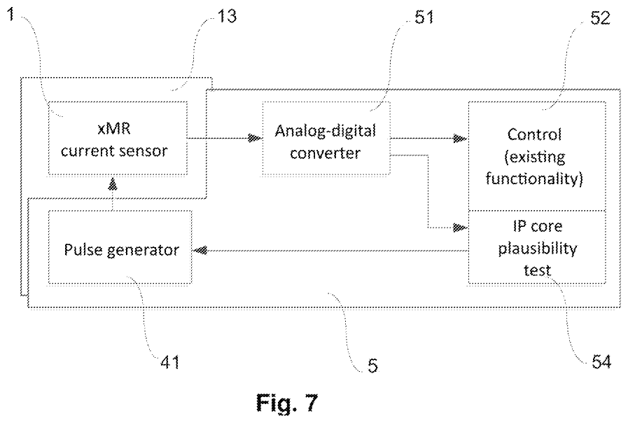

A further construction of the device for detecting a faulty operation of the current sensor 1 is shown in FIG. 7. Through the use of a ready-made IP core 54 (intellectual property core) in programmable modules (e.g., FPGA microcontroller) for this test method as implemented software/firmware or hardware programs, the integration of this test method can be carried out in a very simple manner in or on existing controllers 52 of a sensor circuit 5. In this regard, the type of controller 52 (e.g., microprocessor, digital signal processor [DSP], microcontroller or FPGA) used is not important. This enables a universal and simple implementation and utilization of the test method in new developments or as an expansion of existing measurement systems with xMR current sensor 1. The units necessary for the method can be located anywhere in a sensor circuit 5 (e.g., circuit board), i.e., the test current generator 4 can be a stand-alone unit or can be located either on the carrier printed circuit board 13 of the xMR current sensor 1 or on a circuit board of the sensor circuitry 5.

A further construction consists in that a sensor chip is processed using thin-film technology on a silicon wafer in a kind of multilayer technique. This comprises structured inner layers and various forms of vias for the conductor loop.

Accordingly, the possibilities for the realization and use of this test method according to the invention for magnetic-field-sensitive current sensors 1 is practically unlimited, from vehicle drives, power electronics in aircraft, ships and spaceflight to the monitoring of fast chargers or frequency inverters. In particular, by means of this method, demanding safety requirements, from simple built-in self-test (BIST) to complex test sequences during active device operation, can be met quickly and precisely to ensure functional safety (e.g., SIL level and ASIL level, failure safety, and so on). For this reason, the configurations disclosed herein describe only simple, cost-effective exemplary embodiments for the retrofitting of known xMR current sensors 1. However, the implementation of these embodiments in IC current sensors also falls within the scope of the present invention.

### REFERENCE CHARACTERS

1 current sensor (magnetic-field-sensitive current sensor)
11 measurement plane
12 measuring region
13 carrier printed circuit board
2 (sensed) conductor loop (or busbar)
21 main current path
3 test conductor loop
31 test conductor layer
32 test conductor path
33 test conductor path portion
4 test current generator
41 pulse generator (switching transistor)
42 pulse length limiter (capacitor in RC element)
43 current limiter (fixed resistor)
44 input of test current generator
45 MOSFET
46 (monostable) multivibrator
47 microcontroller (for controlling the pulse length)
5 sensor circuitry
51 ADC (analog-to-digital converter)
52 controller (microprocessor, microcontroller)
53 (switchable) output pin (GPOI pin)
54 IP core (for implementing the test method)
6 power supply
I_{T} test current
I_{D} (amount of) current difference

1. A device for detecting a faulty operation of a current sensor based on a magnetic-field-sensitive sensor element, comprising:
a sensed busbar or conductor loop which is formed in a measurement plane of the current sensor and which can be sensed by the current sensor at least in a measuring region,
a test conductor loop arranged in spatial proximity to the busbar or conductor loop to be sensed by the current sensor,
wherein the test conductor loop is arranged in a plane which is parallel to the measurement plane of the sensed busbar or conductor loop and is adapted to a main current path predetermined by the busbar or conductor loop such that a modulated test current introduced into the test conductor loop can be sensed by magnetic-field-sensitive sensing in the measuring region of the current sensor together with a current of the main current path.

2. The device according to claim 1, wherein the test conductor loop is connected to a test current generator for generating the modulated or pulsed test current.

3. The device according to claim 1, wherein the test conductor loop and the test current generator are galvanically isolated from the sensed conductor loop.

4. The device according to claim 1, wherein the test conductor loop is formed under the current sensor as a test conductor path parallel to the predetermined main current path of the conductor loop.

5. The device according to claim 1, wherein the test conductor loop is provided as a test conductor layer which is parallel to the predetermined measurement plane of the conductor loop and has test conductor paths parallel to the predetermined main current path of the conductor loop and is integrated by multilayer thin-film technology on a sensor printed circuit board of the current sensor.

6. The device according to claim 1, wherein the test conductor loop is provided as a test conductor layer which is parallel to the predetermined measurement plane of the conductor loop and has test conductor paths parallel to the predetermined main current path of the conductor loop and is realized as a conductive frame in one or more layers on a chip of the magnetic-field-sensitive sensor element of the current sensor.

7. The device according to claim 1, wherein the test conductor loop is formed as a helical shape with a plurality of parallel conductor path portions with respect to the predetermined main current path of the conductor loop sensed by the current sensor.

8. The device according to claim 1, wherein the test current generator is a pulse generator for generating defined current pulses.

9. The device according to claim 8, wherein the test current generator has at least one switching transistor for generating pulses, a pulse length limiter and a current limiter.

10. The device according to claim 8, wherein the test current generator has a series capacitor as a pulse length limiter and a fixed resistor as a current limiter.

11. The device according to claim 9, wherein the switching transistor is formed by at least one element from the group consisting of unipolar transistors, bipolar transistors, thyristors and an optoelectronic switching element.

12. The device according to claim 8, wherein the test current generator has a pulse generator for generating individual pulses of a rectangular pulse, a sawtooth pulse or sine pulses, or for generating pulse sequences therefrom as a recurrence of identical or different pulse shapes, or is configured to generate a freely defined pulse sequence which can be learned for evaluation using pattern recognition algorithms.

13. A method for detecting a faulty operation of a current sensor based on a magnetic-field-sensitive effect in a busbar or conductor loop sensed for current measurement, comprising the following steps:
A. providing an additional sensable test conductor loop arranged adjacent to the busbar or conductor loop sensed in a magnetic-field-sensitive manner by the current sensor for applying a modulated test current,
B. detecting first measurement values with the current sensor for successive current measurement and current monitoring in a predetermined measuring region of the sensed busbar or conductor loop,
C. generating a pulse-modulated test current with the test current generator,
D. introducing the modulated test current into the test conductor loop in a temporally limited manner,
E. detecting at least a second measurement value through current measurement with the current sensor with overlaying of magnetic fields of the test current in the test conductor loop and of the current in the busbar or conductor loop which is sensed in a magnetic-field-sensitive manner by the current sensor, and
F. determining a differential current from the first and second measurement values and evaluating the differential current for detecting deviations of the differential current from an introduced waveform of the test current.

14. The method according to claim 13, wherein the test current is provided as an individual pulse.

15. The method according to claim 13, wherein the test current is provided as a defined pulse sequence.

16. The method according to claim 14, wherein the test current is provided as a rectangular pulse, sawtooth pulse or sine pulse, a or in a pulse sequence thereof as a recurrence of identical or different pulses.

17. The method according to claim 15, wherein the test current is provided as a rectangular pulse, sawtooth pulse or sine pulse or in a pulse sequence thereof as recurrence of identical or different pulses.

18. The method according to claim 15, wherein the test current is generated as a freely defined pulse sequence which can be learned for evaluation using pattern recognition algorithms.

19. The method according to claim 16, wherein the test current is generated as freely defined pulse sequence which can be learned for evaluation preferably with pattern recognition algorithms.
